(19) United States
(12) Patent Application Publication
(10) Pub. No.: US 2017/0168100 A1
(43) Pub. Date: Jun. 15, 2017

(54) PULSE GENERATING APPARATUS AND CALIBRATING METHOD THEREOF

(71) Applicant: CHROMA ATE INC., Taoyuan (TW)

(72) Inventors: Cheng-Hsien CHANG, Taoyuan (TW); Ching-Hua CHU, Taoyuan (TW)

(73) Assignee: CHROMA ATE INC., Taoyuan (TW)

(21) Appl. No.: 15/373,311

(22) Filed: Dec. 8, 2016

(30) Foreign Application Priority Data
Dec. 9, 2015 (TW) 104141400

(51) Int. Cl. G01R 29/02

(52) U.S. Cl. CPC G01R 29/02

(57) ABSTRACT

A pulse generating apparatus capable of calibration and calibrating method are disclosed. The pulse generating apparatus includes a pulse generator and a delay detector. The pulse generator is configured to repeatedly generate a testing pulse. The delay detector is electrically connected with the pulse generator. When the pulse generator generates the testing pulse, the delay detector detects a feature value of the testing pulse at a plurality detecting time points, and calculates a calibration value according to the detected feature values. The delay detector outputs the calibration value to the pulse generator and the pulse generator adjusts the testing pulse according to the calibration value.

### CROSS-REFERENCE TO RELATED APPLICATIONS

This non-provisional application claims priority under 35 U.S.C. §119(a) on Patent Application No(s). 104141400 filed in Taiwan, R.O.C. on Dec. 9, 2015, the entire contents of which are hereby incorporated by reference.

### TECHNICAL FIELD

The disclosure relates to a pulse generating apparatus capable of calibration and a calibrating method thereof, more particularly to a pulse generating apparatus capable of calibration and a calibrating method thereof adopted for generating semiconductor testing pulse.

### BACKGROUND

The production of semiconductor chip increases in line with the progress of high-tech product. To meet the production demand, not only for semiconductor chip manufacturers to dive into the research of fabrication technology and process, end product testing after semiconductor chips were manufactured is also a key point for those semiconductor chip manufacturers.

In semiconductor testing, testing pulses with different pulse period and duty cycle are required to test semiconductors for any kinds of testing. Since accuracy is of essential for testing pulses used in semiconductor testing, the timing of signal rising and falling cannot always meet the predetermined values in the conventional measurement of generating testing pulses through just by setting, which makes the width of the testing pulses to be out of expectation.

### SUMMARY

According to the pulse generating apparatus of an embodiment of the present disclosure, it comprises a pulse generator and a delay detector. The pulse generator is configured to repeatedly generate a testing pulse. The delay detector is electrically connected with the pulse generator. When the pulse generator generates the testing pulse, the delay detector detects a feature value of the testing pulse at a plurality detecting time points, and calculates a calibration value according to the detected feature values. The delay detector outputs the calibration value to the pulse generator and the pulse generator adjusts the testing pulse according to the calibration value.

According to the method for calibrating pulse generating apparatus of an embodiment of the present disclosure, the method comprises: generating a testing pulse repeatedly by a pulse generator; detecting a feature value of the testing pulse at each detecting time point of a plurality of detecting time points when the pulse generator generates the testing pulse; generating a simulation pulse according to the detected feature values; and adjusting the testing pulse according to the calibration value.

According to the pulse generating apparatus and the calibrating method thereof of an embodiment of the present disclosure, by a plurality of testing pulses generated by the pulse generator, the delay detector may obtain a plurality of feature values at each of a plurality of detecting time points when the pulse generator generates the testing pulse, to determine the waveform of the testing pulse, and further to determine the calibration value of the adjusted testing pulse. The pulse generator adjusts the testing pulse according to the calibration value, and then outputs the adjusted testing pulse to an object to be tested, for the object to run testing.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a schematic view illustrating the functional block of the pulse generator of an embodiment of the present disclosure;

FIG. 2 is a schematic view illustrating the functional block of the pulse generator of another embodiment of the present disclosure;

FIG. 3 is a schematic view illustrating the feature values of testing pulses detected at a plurality of detecting time points;

FIG. 4 is a schematic view illustrating the testing pulse, simulation pulse and the adjusted pulse of an embodiment of the present disclosure;

FIG. 5 is a schematic view illustrating the flowchart of the method for calibrating of an embodiment of the present disclosure; and

FIG. 6 is a schematic view illustrating the flowchart of the method for calibrating of another embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

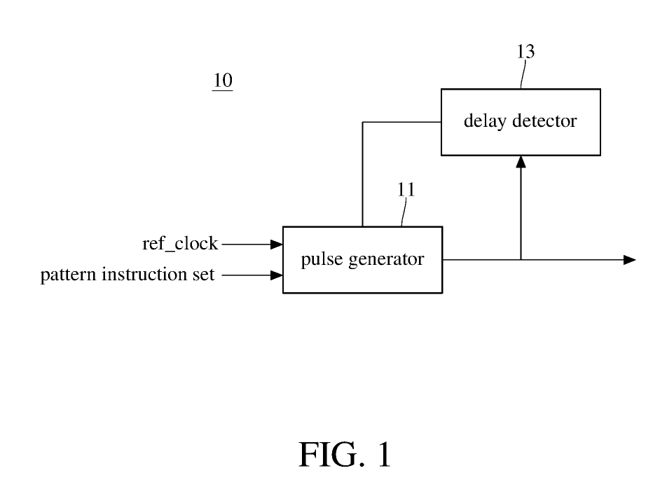

FIG. 1 is a schematic view illustrating the functional block of the pulse generator of an embodiment of the present disclosure. As shown in FIG. 1, the pulse generating apparatus 10 comprises a pulse generator 11 and a delay detector 13. The pulse generator 11 repeatedly generates a testing pulse. The delay detector 13 electrically connects with the pulse generator 11. The delay detector 13 detects a feature values at each detecting time point of a plurality of detecting time points when the pulse generator 11 generates the testing pulse, and calculates a calibration value according to the detected feature values. The delay detector 13 outputs the calibration value to the pulse generator 11 so as to make the pulse generator 11 to adjust the testing pulse according to the calibration value.

To be more specific, the pulse generator 11 generates testing pulses based on the a reference clock ref_clock and a pattern instruction set, and the pulse generator 11 repeatedly outputs the testing pulses to a predetermined time (e.g. 800 times) before outputting the testing pulses to an object to be tested. The delay detector 13 detects a feature values at each of the plurality of detecting time points when the pulse generator 11 generates the testing pulse, for example, to detect the feature values of 100 detecting time points each time. In other words, the delay detector 13 detects 80000 feature values in total and the delay detector 13 then calculates the calibration value according to the 80000 feature values. The feature value may be the voltage value of the testing pulse at a detecting time point, the difference with a low level voltage or other suitable feature value. The calibration value may be the time calibration value to the waveform, calibration value to voltage or other suitable calibration value, and would be described in more detail in the following description.

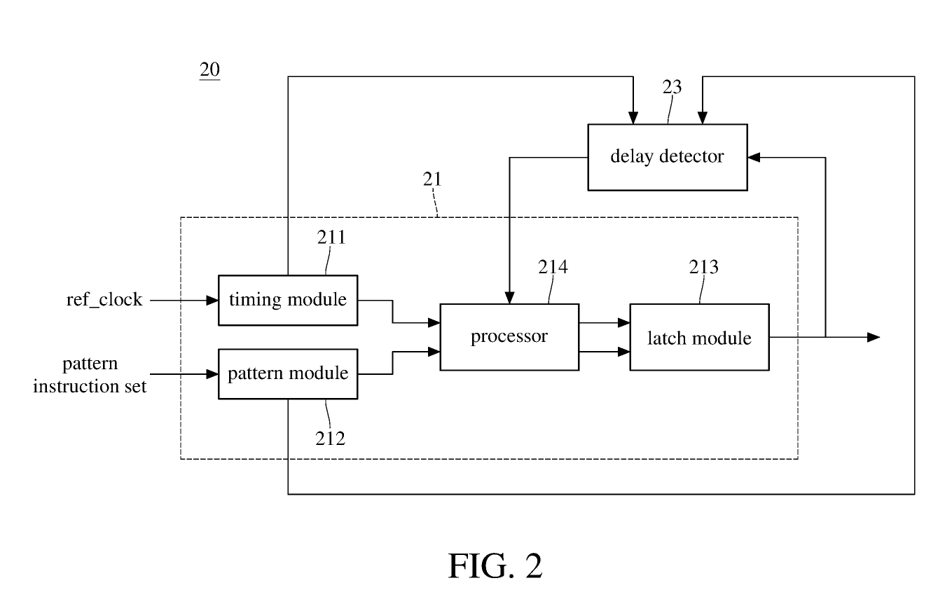

FIG. 2 is a schematic view illustrating the functional block of the pulse generator of another embodiment of the present disclosure. In another embodiment as shown in FIG. 2, the pulse generator 21 comprises a timing module 211, a pattern module 212, a latch module 213 and a processor 214. The timing module 211 is configured to generate a triggering time data which defines a plurality of triggering time points. The pattern module 212 is configured to generate a pattern data which defines the waveform of the testing pulse of each triggering time point. The processor 214 electrically connects with the timing module 211, the pattern module 212 and the latch module 213, and is configured to receive the triggering time data and pattern data generated respectively by the timing module 211 and pattern module 212, and to generate a control signal and a reset signal to the latch module 213 according to the triggering time data and the pattern data. The latch module 213 is configured to generate the testing pulse according to the control signal and the reset signal.

In more detail, the timing module 211 has a timer. The timing module 211 generates a triggering signal by counting the period of the reference clock ref clock, and then outputs the triggering signal to the processor 214. The processor 214 receives the triggering signal and the pattern data generated by the pattern module 212, and generates at the triggering time of each triggering signal the control signal and reset signal to the latch module 213 to control the latch module 213 to generate the testing pulse. The latch module 213 may be such as S-R latch or other latches. The latch module 213 has a setting input terminal and a resetting input terminal. The setting input terminal receives the control signal, and the resetting input terminal receives the reset signal. In one embodiment, the testing pulse outputted by the latch module 213 is raised up to high level voltage when the setting input terminal receives the control signal. When the resetting input terminal receives the reset signal, the testing pulse outputted by the latch module 213 is pulled down to low level voltage.

Although the triggering time data of the timing module 211 and the pattern data of the pattern module 212 define the predetermined waveform of the testing pulse, however, the testing pulse outputted by the latch module 213 may not in practice be rapidly raised up to high level voltage when under rising-edge triggering, and may not be rapidly pulled down to low level voltage when under falling-edge triggering, which means time delay exists between the actually outputted testing pulse and the predetermined testing pulse. For voltage value of the waveform point of view, the predetermined testing pulse should be reaching to high level voltage at triggering time point T1, such as 1V, but the outputted testing pulse is actually just about to trigger and rise at triggering time point T1. High level voltage 1V is reached until T1+ΔT, which makes the width of the testing pulse at positive level to be different from the predetermined width, which further effects the accuracy for pulse width modulation.

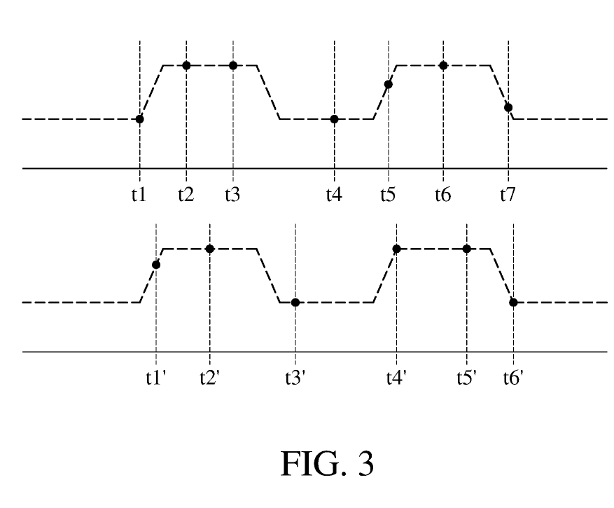

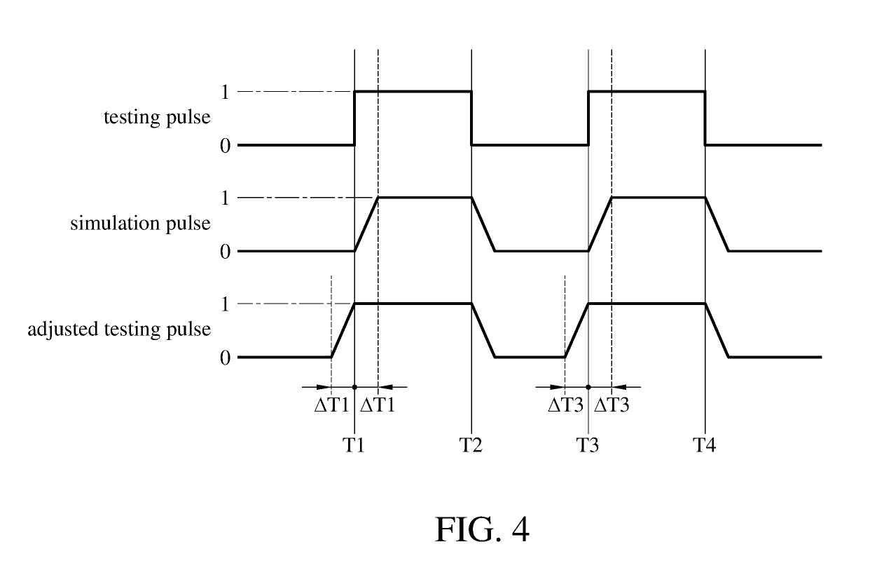

Therefore, during calibration period of the pulse generator 21, testing pulses are repeatedly outputted to a predetermined time; and during calibration period of the delay detector 23, it detects a feature value at each detecting time point of a plurality of detecting time points when the pulse generator 21 generates the testing pulse. The following description would be described with reference of both FIG. 3 and FIG. 4.

Please refer to FIG. 2 to FIG. 4, where FIG. 3 is a schematic view illustrating the feature values of testing pulses detected at a plurality of detecting time points, and FIG. 4 is a schematic view illustrating the testing pulse, simulation pulse and the adjusted pulse of an embodiment of the present disclosure. As shown in the Figs, during calibration period, when the pulse generator 21 generates once the testing pulse, the delay detector 23 detects respectively the voltage value of the testing pulse at each detecting time point t1˜t7, and when the pulse generator 21 generates the next testing pulse, the delay detector 23 detects respectively the voltage value of the testing pulse at each detecting time point t1′˜t6′. The delay detector 23 generates a simulation pulse as shown in FIG. 4 according to the voltage value detected at detecting time points t1˜t7 and detecting time points t1′˜t6′.

The delay detector 23 receives the triggering time data and pattern data generated respectively from the timing module 211 and the pattern module 212, and determines the predetermined testing pulse according to the triggering time data and pattern data. To be more specific, triggering time data defines triggering time points T1˜T4, pattern data defines that triggering time points T1 and T3 to be the timing for rising-edge triggering and triggering time points T2 and T4 to be the timing for falling-edge triggering. The predetermined testing pulse determined by the delay detector 23 according to the triggering time data and pattern data is shown as in FIG. 4.

The delay detector 13 compares the simulation pulse and the predetermined testing pulse as shown in FIG. 4, and then determines the delay time ΔT1 of the firstly rising-triggered high level voltage of the simulation pulse, and the delay time ΔT2 of the secondly rising-triggered high level voltage of the simulation pulse. The delay detector 23 treats the delay time ΔT1 as a calibration value for triggering time point T1, and treats the delay time ΔT3 as a calibration value for triggering time point T3. The delay detector 23 outputs delay time ΔT1 and delay time ΔT3 to the processor 214. The processor 214 calibrates the triggering time data according to delay time ΔT1 and delay time ΔT3, such as to advance delay time ΔT1 for triggering time point T1 and to advance delay time ΔT3 for triggering time point T3.

During semiconductor testing period, the pulse generator 21 generates the control signal and reset signal according to the calibrated triggering time data and pattern data, which means to make the testing pulse to be rising-triggered during triggering time point T1-ΔT1 and triggering time point T3-ΔT3 in order to generate calibrated testing pulse for semiconductor auto-testing equipment or other testing equipment, making the semiconductor auto-testing equipment or other testing equipment to test semiconductor according to the calibrated testing pulse.

In the previous embodiment, for convenience purposes, to calibrate the timing of rising-edge triggering is taken as an example. However, in other embodiments, to calibrate the timing of falling-edge triggering single-handedly, or to calibrate the timing of both rising- and falling-edge triggering to calibrate the testing pulse is also adoptable. Moreover, in the embodiment shown in FIG. 3, outputting two testing pulse is an exemplary for describing, not to limit how many times the pulse generator generates the testing pulse. Furthermore, the present embodiment does not limit how many times the delay detector 23 detects each of the testing pulse.

For more detail descriptions to the waveform generating apparatus capable of calibration and a calibrating method thereof, FIG. 1-FIG. 5 are referred to simultaneously.

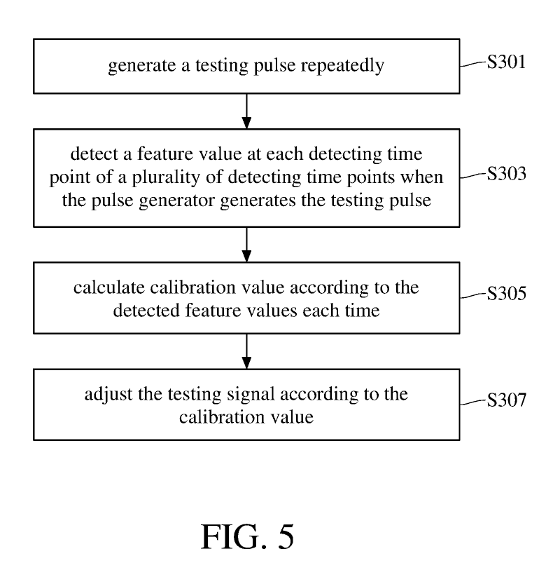

FIG. 5 is a schematic view illustrating the flowchart of the method for calibrating of an embodiment of the present disclosure. As shown in FIG. 5, in step S301: the pulse generator 11 generates a testing pulse repeatedly. In step 303: the delay detector 13 detects a feature value at each detecting time point of a plurality of detecting time points when the pulse generator 11 generates the testing pulse. In step 305: the delay detector 13 calculates the calibration value according to the detected feature values each time, and then outputs the calibration value to the pulse generator 11. In step 307: the pulse generator 11 adjusts the testing pulse according to the calibration value, for testing semiconductor. In the present embodiment, the detail descriptions for the calibration method has been described in the previous paragraphs, and thus are omitted here for precise purpose.

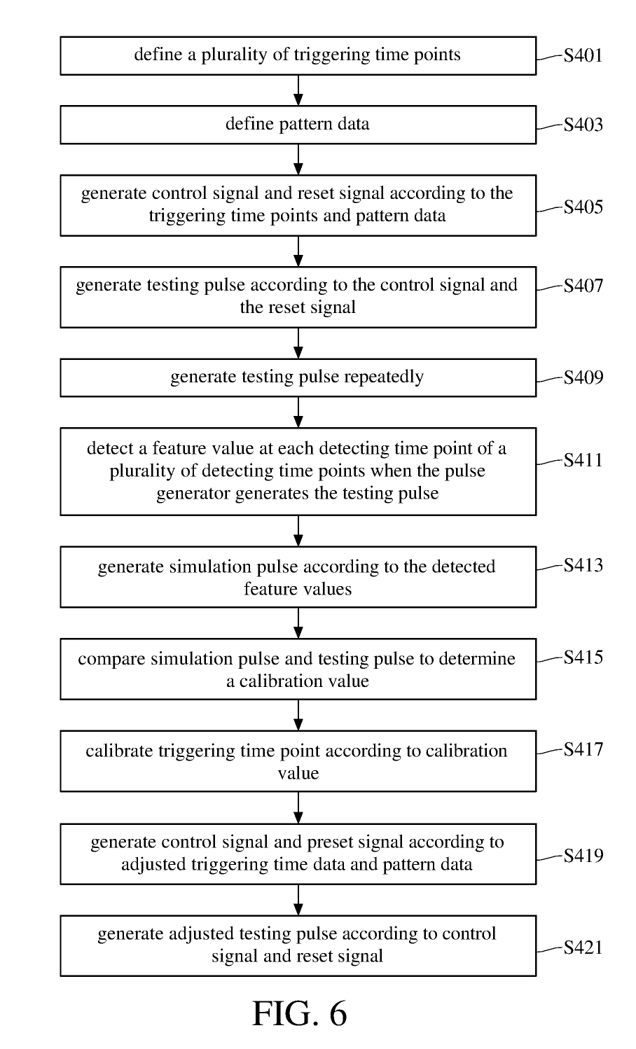

In another embodiment, please refer to FIG. 2 and FIG. 6, where FIG. 6 is a schematic view illustrating the flowchart of the method for calibrating of another embodiment of the present disclosure. As shown in FIG. 6, in step S401: the timing module 211 defines a plurality of triggering time points. In step S403: the pattern module 212 defines pattern data associated with the waveform of the testing pulse of each triggering time point. In step S405: the processor 214 generates control signal and reset signal according to the triggering time points and pattern data. In step S407: the latch module 217 generates testing pulse according to the control signal and the reset signal. In step S409: the pulse generator 21 generates testing pulse repeatedly. In step S411: the delay detector 23 detects a feature value at each detecting time point of a plurality of detecting time points when the pulse generator 21 generates the testing pulse. In step S413: the delay detector 23 generates simulation pulse according to the detected feature values. In step S415: the delay detector 23 compares the simulation pulse and the testing pulse to determine a calibration value, and outputs the calibration value to the processor 214. In step S417: the processor 214 calibrates the triggering time point according to calibration value. In step S419: the processor 214 generates control signal and preset signal according to calibrated triggering time data and pattern data. In step S421: the latch module 213 generates calibrated testing pulse according to control signal and reset signal. In the present embodiment, the detail descriptions for the calibration method has been described in the previous paragraphs, and thus are omitted here for precise purpose.

In summary, a pulse generating apparatus capable of calibration and a calibrating method thereof is provided. By detecting the outputted testing pulse and calibrating the testing pulse before the pulse generating apparatus outputs testing pulse to a semiconductor auto-testing equipment or other testing equipment, in-time measurement and in-time feedback control may be avoided, which may cause inaccuracies for the outputted testing pulses. Furthermore, according to the present disclosure, the pulse generator outputs a plurality of testing pulses during a long-enough calibration period, which makes the delay detector capable of detecting the testing pulses at different detecting time point when every time the pulse generator outputs the testing pulse, which further decreases the detecting frequency of the delay detector, which then decreases the efficiency spec, which then decreases the costs for the pulse generator.

What is claimed is:

1. A pulse generating apparatus, comprising:
a pulse generator, configured to repeatedly generate a testing pulse; and
a delay detector electrically connected with the pulse generator;
wherein the delay detector detects a feature value of the testing pulse at each detecting time point of a plurality of detecting time points when the pulse generator generates the testing pulse, and generates a simulation pulse according to the detected feature values;
wherein the delay detector compares the simulation pulse and a predetermined testing pulse to determine a calibration value, and outputs the calibration value to the pulse generator so as to make the pulse generator to adjust the testing pulse according to the calibration value.

2. The pulse generating apparatus as claimed in claim 1, wherein the pulse generator further comprises:
a timing module, configured to generate a triggering time data which defines a plurality of triggering time points;
a pattern module, configured to generate a pattern data which defines a waveform of the testing pulse of each triggering time point;
a latch module, configured to generate the testing pulse according to a control signal and a reset signal; and
a processor, electrically connected with the timing module, the pattern module and the latch module, and configured to generate the control signal and the reset signal according to the triggering time data and the pattern data.

3. The pulse generating apparatus as claimed in claim 2, wherein the processor further electrically connects with the delay detector, the processor adjusts the triggering time points of the triggering time data according to the calibration value, and generates the control signal and the reset signal according to the adjusted triggering time data and the pattern data.

4. The pulse generating apparatus as claimed in claim 1, wherein the calibration value associates with a delay time between the simulation pulse and the predetermined testing pulse, and the pulse generator adjusts the testing pulse according to the delay time.

5. A method for calibrating pulse generating apparatus, comprising:
generating a testing pulse repeatedly by a pulse generator;
detecting a feature value of the testing pulse at each detecting time point of a plurality of detecting time points when the pulse generator generates the testing pulse;
generating a simulation pulse according to the detected feature values;
comparing the simulation pulse and a predetermined testing pulse to determine a calibration value; and
adjusting the testing pulse according to the calibration value.

6. The method for calibrating pulse generating apparatus as claimed in claim 5, further comprising:
defining a plurality of triggering time points;
defining a pattern data associated with a waveform of the testing pulse of each of the triggering time points;
generating a control signal and a reset signal according to the triggering time points and the waveform of the testing pulse of each of the triggering time points; and
generating the testing pulse according to the control signal and the reset signal.

7. The method for calibrating pulse generating apparatus as claimed in claim 6, further comprising adjusting the triggering time points according to the calibration value, and generating the control signal and the reset signal according to the adjusted triggering time points and the pattern data.

8. The method for calibrating pulse generating apparatus as claimed in claim 5, wherein the calibration value associates with a delay time between the simulation pulse and the predetermined testing pulse, and the step of adjusting the testing pulse according to the calibration value further comprises to adjust the testing pulse according to the delay time.
